(19) United States
(12) Patent Application Publication
(10) Pub. No.: US 2007/0163995 A1
(43) Pub. Date: Jul. 19, 2007

(54) PLASMA PROCESSING METHOD, APPARATUS AND STORAGE MEDIUM

(75) Inventors: Masaru SUGIMOTO, Nirasaki-shi (JP); Noriyuki Kobayashi, Nirasaki-shi (JP); Masaharu Sugiyama, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/567,384

(22) Filed: Dec. 6, 2006

Related U.S. Application Data
(60) Provisional application No. 60/771,439, filed on Feb. 9, 2006.

(30) Foreign Application Priority Data
Jan. 17, 2006 (JP) 2006-009000

(51) Int. Cl. C23F 1/00; B44C 1/22; H01L 21/302; H01L 21/306

(52) U.S. Cl. 216/67; 156/345.47; 438/710

(57) ABSTRACT

In etching an insulating film such as an SiOC film or the like, in order to suppress a diameter of a hole or a width of a groove, a pre-processing is performed before performing the etching. In the pre-processing, a processing gas containing CF₄ gas and CH₃F gas is converted into a plasma, and an opening size of an opening portion of a resist mask is decreased by depositing deposits at a sidewall thereof by using the plasma. Further, in etching the SiOC film, a processing gas containing CF₄ gas, CH₃F gas, and N₂ gas is converted into a plasma by supplying a processing gas atmosphere by using a first high frequency wave for generating the plasma, wherein the electric power divided by a surface area of a substrate becomes over 1500 W/70685.8 mm² (a surface area of a 300 mm wafer), and then the SiOC film is etched.

### FIELD OF THE INVENTION

The present invention relates to a plasma processing method for performing a process on an insulation film, which is formed with a low-k film containing silicon and oxygen, by using plasma; an apparatus for same; and a storage medium for storing therein a computer program for carrying out the method.

### BACKGROUND OF THE INVENTION

A semiconductor device tends to be more highly integrated year after year and, a resist material and an exposure technique are being improved, accordingly, in order to meet the challenge corresponding to a miniaturization of patterns formed on a wafer. Thus, an opening size of a resist mask is getting smaller.

Further, since the semiconductor device becomes to have a multilayered structure to achieve the high-integration of the device while a parasitic capacitance thereof is required to be reduced to improve its operational speed, a material of a low-k film for an insulating film (e.g., also for an interlayer insulating film) is being developed. An SiOC film, which is referred to as a carbon containing silicon oxide film, is an example of the low-k film.

As described above, though the high-integration of the semiconductor device with a high operational speed can be achieved by combining a resist mask forming technique and the low-k film, a series of these processes has a drawback that a recessed portion is widened during an etching process To be specific, if an etching is performed by using a plasma, the opening size of the resist mask may be widened or a sidewall of the recessed portion of an etching target film can be etched excessively. Accordingly, a hole or a groove becomes wider than a design value thereof so that characteristics of the device cannot be achieved as designed Further, if edges of the adjacent holes (via holes or contact holes for burying electrodes) approach closer to each other due to the widening of the holes, the holes can be short-circuited, thereby putting a further limit on the resist mask forming technique. Therefore, a technique for forming a recessed portion of a size smaller than the opening size of the resist mask on the etching target film is also needed.

Methods for managing the aforementioned problems are proposed in Japanese Patent Laid-open Application No. 2004-103925 (claim 11 and paragraph 0107: Reference 1) and Japanese Patent Laid-open Application No. 2004-247568 (paragraph 0010: Reference 2). In Reference 1, SF₆ is used as a first etching gas; and at least one of CF₄, CHF₃, CH₂F₂ and CH₄ is used as a second etching gas, for a silicon nitride film. Reference 1 describes that it is possible to adjust a pattern size in an etching by using such gas mixture, but it is not an appropriate process for etching films containing silicon and oxygen, e.g., an SiOC film. Further, though Reference 2 proposes an SiOC film etching method using a gas mixture containing CF₄, CHF₃, N₂ and inert gas, an electric power to be supplied to the processing gas is not considered. Thus, it cannot be called as an effective method for suppressing the widening of the recessed portion such as the hole or the groove.

### SUMMARY OF THE INVENTION

In view of the above-described prior art problems, an object of the present invention is to form a recessed portion, which has a small opening size, on a substrate such as a semiconductor wafer (hereinafter, referred to as a ‘wafer’), in etching an insulating film made of a low-k film containing silicon and oxygen; and, more particularly, to provide a plasma processing method for forming a recessed portion, which has a smaller size than the opening size of an opening portion formed at a resist mask, on a substrate, and a plasma processing apparatus for same. Further, another object of the present invention is to provide a storage medium for storing a computer program for executing such plasma processing.

In accordance with a first aspect of the present invention, there is provided a plasma processing method for processing a substrate by using a plasma processing apparatus having a first high frequency power supply, wherein the first high frequency power supply is connected to one of an upper electrode and a lower electrode facing to each other and supplies a first high frequency wave to a processing gas atmosphere in order to convert a processing gas into plasma, the method including the steps of:

mounting the substrate, in which a resist mask is laminated on an insulating film made of a low-k film containing silicon and oxygen, on the lower electrode;

supplying the processing gas, which contains CF-based compound made of carbon and fluorine and CHₓF_{y} (a sum of x and y equals four, each of them being a natural number), to the processing gas atmosphere;

generating a plasma by converting the processing gas into plasma by supplying the first high frequency wave to the processing gas atmosphere, and decreasing an opening size of an opening portion of the resist mask by depositing deposits at a sidewall thereof; and

etching the insulating film by using the plasma.

Preferably, the first high frequency power supply is connected to the upper electrode; and the step for decreasing the opening size is performed while a bias power is supplied to the substrate mounted on the lower electrode, by supplying a second high frequency wave, which has a frequency lower than that of the first high frequency wave, to the processing gas atmosphere by using a second high frequency power supply connected to the lower electrode.

Preferably, the resist mask can be formed directly on the insulating film as well as on an antireflection film for preventing reflection during an exposure disposed between the insulating film and the resist mask. Further, an oxide film, such as an SiO₂ film, can be disposed between the insulating film and the antireflection film. Preferably, the insulating film is an oxide film such as an SiOC film, SiOCH film, an SiO₂ film, or the like.

Preferably, an electric power of the first high frequency wave supplied to the upper electrode or the lower electrode divided by a surface area of the substrate is equal to or greater than 1000 W/70685.8 mm². Further, preferably, a flow rate ratio of the CHₓF_{y} gas to the CF-based gas is equal to or greater than 0.05.

In accordance with a second aspect of the present invention, there is provided a plasma processing method for processing a substrate by using a plasma processing apparatus having a first high frequency power supply and a second high frequency power supply, wherein the first high frequency power supply is connected to one of an upper electrode and a lower electrode facing to each other and supplies a first high frequency wave to a processing gas atmosphere in order to convert a processing gas into a plasma; and wherein a second high frequency power supply is connected to the lower electrode and supplies a second high frequency wave, which has a frequency lower than that of the first high frequency wave, to the processing gas atmosphere in order to supply a bias power to the substrate mounted on the lower electrode, the method including the steps of:

mounting the substrate, in which a resist mask is laminated on an insulating film made of a low-k film containing silicon and oxygen, on the lower electrode;

supplying the processing gas, which contains CF₄, CHₓF_{y} (a sum of x and y equals four, each of them being a natural number) and N₂, to the processing gas atmosphere; and

generating a plasma by converting the processing gas into the plasma by supplying the first high frequency wave to the processing gas atmosphere, wherein an electric power supplied to the upper electrode or the lower electrode by the first high frequency wave divided by a surface area of the substrate is equal to or greater than 1500 W/70685.8 mm², and etching the insulating film by using the plasma by supplying the second high frequency wave to the processing gas atmosphere.

It is preferable that the process condition used in the plasma processing method in accordance with the second aspect of the present invention is applied to (i.e., combined with) the step of etching the insulating film in the plasma processing method of the first aspect which decreases the opening size of the resist mask. Preferably, a flow rate ratio of the CF₄ gas to the CHₓF_{y} gas is equal to or greater than 0.2 and equal to or smaller than 2.

In accordance with a third aspect of the present invention, there is provided a plasma processing apparatus for etching an insulating film of a substrate in which a resist mask is laminated on the insulating film made of a low-k film containing silicon and oxygen, the apparatus including:

a processing chamber;

an upper electrode and a lower electrode disposed in the processing chamber to face to each other;

a first high frequency power supply, wherein the first high frequency power supply is connected to one of the upper electrode and the lower electrode and supplies a first high frequency wave to a processing gas atmosphere in order to convert a processing gas into a plasma;

a supply unit for supplying the processing gas, which contains CF-based compound made of carbon and fluorine and CHₓF_{y} (a sum of x and y equals four, each of them being a natural number), to the processing chamber; and

a control unit for performing the plasma processing method.

Preferably, the plasma processing apparatus includes, a first high frequency power supply connected to the upper electrode; and

a second high frequency power supply, wherein the second high frequency power supply is connected to the lower electrode and supplies a second high frequency wave, which has a frequency lower than that of the first high frequency wave, to the processing gas atmosphere in order to supply a bias power to the substrate mounted on the lower electrode In accordance with a forth aspect of the present invention, there is provided a plasma processing apparatus for etching an insulating film of a substrate in which a resist mask is laminated on the insulating film made of a low-k film containing silicon and oxygen, the apparatus including:

a processing chamber;

an upper and a lower electrode disposed in the processing chamber to face to each other;

a first high frequency power supply, wherein the first high frequency power supply is connected to one of the upper electrode and the lower electrode and supplies a first high frequency wave to a processing gas atmosphere in order to convert a processing gas into a plasma;

a second high frequency power supply, wherein the second high frequency power supply is connected to the lower electrode and supplies a second high frequency wave, which has a frequency lower than that of the first high frequency wave, to the processing gas atmosphere in order to supply a bias power to the substrate mounted on the lower electrode;

a supply unit for supplying the processing gas containing CF₄, CHₓF_{y} (a sum of x and y equals four, each of them being a natural number) and N₂, to the processing chamber; and

a control unit for performing the plasma processing method.

In accordance with a storage medium of the present invention,

the storage medium stores therein a computer program to be run on a computer, the program used in a plasma processing apparatus having a first high frequency power supply and a second high frequency power supply, wherein the first high frequency power supply is connected to one of an upper electrode and a lower electrode facing to each other and supplies a first high frequency wave to a processing gas atmosphere in order to convert a processing gas into a plasma; and wherein the second high frequency power supply is connected to the lower electrode and supplies a second high frequency wave, which has a frequency lower than that of the first high frequency wave, in order to supply a bias power to the substrate mounted on the lower electrode. The computer program includes steps for performing the plasma processing method. The computer program includes not only a group of steps formed with instructions but also a database.

In accordance with the plasma processing method of the first aspect of the present invention, in etching the substrate in which the resist mask is laminated on the insulating film (e.g., the SiOC film) made of the low-k film containing silicon and oxygen, a pre-processing, for converting the processing gas containing CF-based gas and CHₓF_{y} gas into a plasma to decrease the opening size by depositing the deposits at the sidewall of the opening portion of the resist mask by using the plasma, is performed before the etching. Since the opening size of the resist mask becomes small due to the pre-processing, even if the recessed portion is widened during the etching of the insulating film, a recessed portion of a small hole-diameter or of a narrow line width can be formed. Accordingly, designed or nearly designed device characteristics can be obtained even in a regime where the target size of the recessed portion is so minute that it is difficult to achieve such size in the opening portion of the mask pattern by the resist mask forming technique. Further, since it is possible to form a recessed portion having an opening size smaller than that of the resist mask on a film to be etched, the electrodes buried in the holes will not be short-circuited even if a distance between the holes (e.g., via holes and/or contact holes) adjacent to each other is reduced.

In accordance with the plasma processing method of the second aspect of the present invention, the insulating film is etched by supplying the first high frequency wave, which is for converting the gas mixture containing CF₄, CHₓF₄, and N₂ gas into a plasma, to the processing gas atmosphere, wherein an electric power supplied to the upper electrode or the lower electrode by the first high frequency wave divided by a surface area of the substrate is equal to or greater than 1500 W/70685.8 mm². From this, as shown in the experimental data, the widening of the recessed portion of the insulating film formed by the etching can be suppressed, thereby achieving perfectly or nearly same device characteristics as designed, and preventing the electrodes or the wirings buried in the recessed portions from being short-circuited even if the distance between recessed portions adjacent to each other is reduced.

Further, a recessed portion of a size smaller than that of the opening portion of the resist mask can be formed by the etching after performing the pre-processing, thereby dealing with the miniaturization of the pattern.

### BRIEF DESCRIPTION OF THE DRAWINGS

The above and other objects and features of the present invention will become apparent from the following description of preferred embodiments given in conjunction with the accompanying drawings, in which:

FIG. 1 is a plan view showing an embodiment of a plasma processing apparatus in accordance with the present invention;

FIGS. 2A to 2D show configurations of a wafer used in the plasma processing in accordance with the present invention;

FIGS. 3A to 3C illustrate configurations of a wafer used in the experimental examples in accordance with the present invention;

FIGS. 4A and 4B present a result of the experimental example 1 in accordance with the present invention;

FIGS. 5A and 5B describe a result of the experimental example 2 in accordance with the present invention;

FIGS. 6A and 6B provide a result of the experimental example 6 in accordance with the present invention; and

FIGS. 7A and 7B depict a result of the experimental example 7 in accordance with the present invention.

### DETAILED DESCRIPTION OF THE PREFERRED EMBODIMENTS

Hereinafter, preferred embodiments of the present invention will be described in detail with reference to the accompanying drawings.

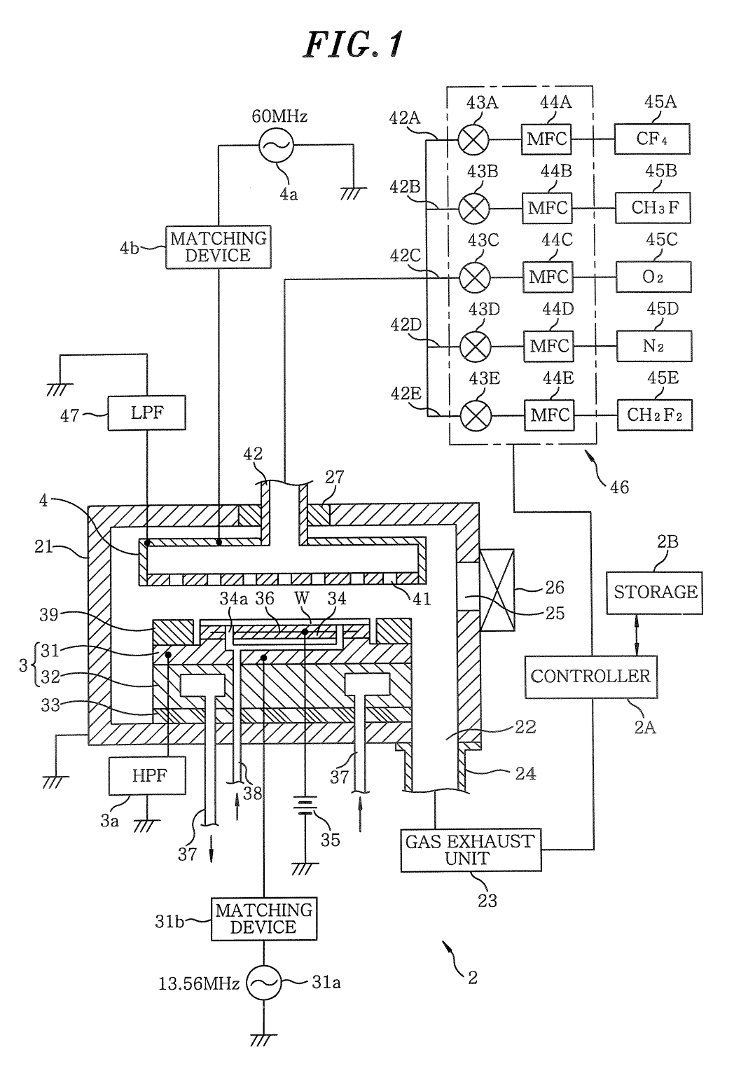

First, an embodiment of a plasma processing apparatus for performing a plasma processing method in accordance with the present invention will be explained by using FIG. 1. A plasma processing apparatus 2 shown in FIG. 1 includes a processing chamber 21, e.g., a vacuum chamber having a sealed inner space; a mounting table 3 disposed at the central portion of the bottom surface inside the processing chamber 21; and an upper electrode 4 disposed above the mounting table 3 to face thereto.

The processing chamber 21 is electrically grounded, and a gas evacuation port 22 disposed at the bottom surface of the processing chamber 21 is connected to a gas evacuation unit 23 via a gas exhaust line 24. The gas evacuation unit 23 is connected with a not shown pressure control unit, and the pressure control unit is configured to maintain the processing chamber 21 at a desired vacuum level by vacuum-evacuating the processing chamber 21 in accordance with a signal from a controller 2A to be described later. At a side surface of the processing chamber 21, a transfer port 25 for a wafer W is provided, and the transfer port 25 can be opened and/or closed with a gate valve 26.

The mounting table 3 has a lower electrode 31 and a supporter 32 for supporting the lower electrode 31 from underside thereof, and is disposed at the bottom surface of the processing chamber 21 with an insulating member 33 disposed therebetween. On the upper portion of the mounting table 3, an electrostatic chuck 34 is provided and the wafer W is mounted on the mounting table 3 with the electrostatic chuck 34 disposed therebetween. The electrostatic chuck 34 is made of an insulating material, and an electrode foil 36 connected with a high voltage DC power supply 35 is provided in the electrostatic chuck 34. The wafer W mounted on the mounting table 3 is electrostatically attracted to the electrostatic chuck 34 due to a static electricity, which is generated at the surface of the electrostatic chuck 34 by allowing the high voltage DC power supply 35 to supply a voltage to the electrode foil 36. At the electrostatic chuck 34, through holes 34a for discharging a backside gas to be described later to the upside of the electrostatic chuck 34 are provided.

Inside the mounting table 3, a coolant channel 37, through which a coolant (e.g., already known fluorine-based fluid, water, etc) flows, is provided. The mounting table 3 is cooled by allowing the coolant to flow through the coolant channel 37, and the wafer W mounted on the mounting table 3 is also cooled to a desired temperature by the cooled mounting table 3. Further, a not shown temperature sensor is attached at the lower electrode 31, and the temperature of the wafer W on top of the lower electrode 31 is constantly monitored thereby.

Further, inside the mounting table 3, a gas channel 38 for supplying a thermal conductive gas (e.g., He gas) as a backside gas is provided. The gas channel 38 is opened at plural locations of the top surface of the mounting table 3 via the through holes 34a disposed at the electrostatic chuck 34. Thus, if a backside gas is supplied to the gas channel 38, the backside gas will be discharged to the upside of the electrostatic chuck 34 via the through holes 34a. By uniformly diffusing the backside gas to a gap between the electrostatic chuck 34 and the wafer W mounted thereon, the thermal conductivity inside the gap can be increased.

The lower electrode 31 is grounded via an HPF (High Pass Filter) 3a, and as a second high frequency power supply, a high frequency power supply 31a (e.g., 13.56 MHz) is connected to the lower electrode 31 via a matching device 31b. Further, on the outer peripheral portion of the lower electrode 31, a focus ring 39 is provided to surround the electrostatic chuck 34 such that a plasma generated therein is made to converge toward the wafer W on the mounting table 3 by the focus ring 39 during the generation of the plasma.

The upper electrode 4 is formed to have a shape of a hollow, and at the bottom surface thereof, a plurality of holes 41 for dispersively supplying the processing gas to the processing chamber 21 is provided (e.g., uniformly dispersed) to form a gas shower head. Further, a gas inlet line 42 is provided at the central portion of the top surface of the upper electrode 4, and the gas inlet line 42 passes through the central portion of the top surface of the processing chamber 21 via an insulating member 27. At the upstream, the gas inlet line 42 branches into five branch lines 42A˜42E to be connected to gas supply sources 45A˜45E via valves 43A˜43E and mass flow controllers 44A˜44E. The valves 43A˜43E and the mass flow controllers 44A˜44E form a gas supply system 46 to control the flow rate and start and stop of gas supplying of respective gas supply sources 45A˜45E on the basis of a control signal from the controller 2A to be described later.

The upper electrode 4 is grounded via an LPF (Low Pass Filter) 47, and as a first high frequency power supply, a high frequency power supply 4a for supplying higher frequency (e.g., 60 MHz) than the frequency supplied by the second high frequency power supply 31a is connected to the upper electrode 4 via a matching device 4b. The high frequency wave supplied by the high frequency power supply 4a, which is connected to the upper electrode 4, corresponds to a first high frequency wave, and is used for converting the processing gas into a plasma. On the other hand, the high frequency wave supplied by the high frequency power supply 31a, which is connected to the upper electrode 31, corresponds to the second high frequency wave, and is used for attracting ions in the plasma to the surface of the wafer W by applying a bias power to the wafer W. Further, the high frequency power supplies 4a and 31a are connected with the controller 2A, thereby controlling the powers supplied to the upper and the lower electrode 4 and 31 in accordance with a control signal.

Further, the plasma processing apparatus 2 is provided with the controller 2A (e.g., configured with a computer), wherein the controller 2A has a data processor, which includes a program, a memory and a CPU. The program is configured with built-in instructions for performing plasma processing on the wafer W by carrying out each step to be described later by allowing the controller 2A to send the control signals to respective parts of the plasma processing apparatus 2. Moreover, the memory has storage areas for storing therein processing parameters such as processing pressures, processing times, gas flow rates, power values and the like, for example, and when the CPU executes each instruction of the program, the parameters are read out in order to send control signals corresponding to the parameters to respective parts of the plasma processing apparatus 2. The program (including a program for input-handling or displaying of processing parameters) is stored in a storage 2B (a computer storage medium, e.g., a flexible disk, a compact disk, an MO (Magnetooptical) disk and the like), and installed on the controller 2A.

Next, an embodiment of a plasma processing method using the plasma processing apparatus 2 in accordance with the present invention will be described. First, after opening the gate valve 26, the wafer W, e.g., 300 mm (12 inches), is loaded into the processing chamber 21 by using a not shown transfer mechanism. After mounting the wafer W on the mounting table 3 horizontally, the wafer W is electrostatically attracted to the mounting table 3. After that, the transfer mechanism is ejected from the processing chamber 21, and then the gate valve 26 is closed. Subsequently, the wafer W is cooled to a specific temperature by the backside gas supplied through the gas channel 38 Thereafter, the following steps are performed.

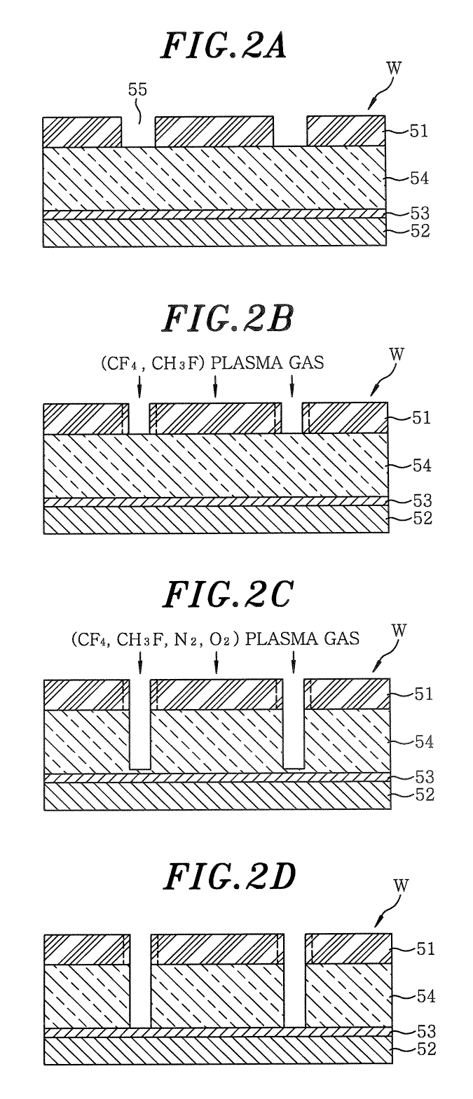

Herein, a structure of the surface of the wafer W in this example is shown in FIG. 2A, wherein an interlayer insulating film is formed on an nth circuit layer and a resist mask 51 made of organic substances as principal components is formed thereon. The reference numerals 51 to 54 indicate the resist mask; an nth Cu wiring layer; an SiC film serving as an etch stopper; and an SiOC film serving as an interlayer insulating film, respectively. In the resist mask 51, an opening portion (hole 55) is provided to form a contact hole at the SiOC film 54, and the diameter of the bottom portion of the hole 55 is 86 nm. As for the thickness of each film, the resist mask 51 is of 200 nm, the SiC film 53 is of 50 nm, and the SiOC film 54 is of 250 nm, for example.

(Step 1: Pre-Processing)

After setting a vacuum level of the processing chamber 21 to a specific value by evacuating the processing chamber 21 via the gas exhaust line 24 by using the gas evacuation unit 23, the gas supply system 46 supplies CF₄ gas and CH₃F gas to the processing chamber 21, under the condition of controlling a flow rate ratio CH₃F/CF₄ (a ratio of a flow rate of CH₃F gas to a flow rate of CF₄ gas) to be in the range of 0.05˜0.2, for example. Subsequently, an electric power of, e.g., 60 MHz, 1000 W or thereabove serving as the first high frequency wave is applied to the upper electrode 4, and an electric power of, e.g., 13.56 MHz, 300 W or thereabove serving as the second high frequency wave is applied to the lower electrode 31, thereby converting the processing gas, which is a gas mixture containing the aforementioned gases, into a plasma. By maintaining such state for a specific period of time, the pre-processing is performed on the wafer W, as shown in FIG. 2B.

By performing the pre-processing, the opening size of the opening portion of the resist mask 51 (i.e., the diameter of the hole 55 in this example) is decreased as clearly shown in the experimental examples to be described later. CH₃F gas mainly generates a plasma for generating deposits, while CF₄ gas mainly generates a plasma for etching the deposits generated. By controlling a flow rate ratio of these gases; a magnitude of the electric power of the first high frequency wave supplied to the upper electrode 4; or a magnitude of the bias power (magnitude of the electric power of the second high frequency wave supplied to the lower electrode 31), a ratio between the deposition rate and the etching rate can be controlled. Further, since the ratio at the vertical surface of the hole 55 and that at the horizontal surface of the hole 55 are different from each other, it is possible to deposit the deposits selectively at the sidewall of the hole 55. For example, if the bias power increases, the ions serving as active species containing fluorine will be more strongly attracted to the wafer W, and thus, the etching process at the bottom surface of the hole 55 becomes stronger than the etching process at the sidewall thereof. By adjusting the bias power, therefore, the etching of the SiOC film 54 can be prevented or suppressed while the deposition of the deposits on the surface of the SiOC film 54 is suppressed. In other words, by setting the bias power to an appropriate value, i.e., to a value wherein the SiOC film 54 is not etched (below 300 W for the wafer W of 300 mm, for example), the deposits can be deposited at the sidewall of the hole 55, thereby decreasing the opening size.

On the other hand, in case of using an apparatus for converting the processing gas into a plasma by supplying the first high frequency wave to the lower electrode 31 (the so-called “lower electrode/dual frequency configuration”), the ions serving as active species containing fluorine will be attracted to the wafer W by the first high frequency wave, so that it is not necessarily required to apply an electric power to the second high frequency wave. Further, by controlling an electric power applied to the first high frequency wave, the deposition of the deposits at the bottom surface of the hole 55 can be suppressed, and also, the etching of the SiOC film 54 can be prevented or suppressed.

Types of the gas used in the pre-processing are not restricted to CF₄ gas or CH₃F gas, but a CF-based gas, e.g., C₂F₆, C₃F₈, and C₄F₈, can be used as the gas for selectively etching the deposits generated. Further, as the gas for generating the deposits, CH₂F₂ gas or CHF₃ gas can be used. Moreover, N₂ gas can be used as a dilution gas, for example.

(Step 2: Main Etching)

After completing the pre-processing, the generation of a plasma in the processing chamber 21 is stopped by stopping the powers supplied from the high frequency power supplies 4a and 31a, and then the gas supply from the gas supply system 46 is stopped. Thereafter, the vacuum level of the processing chamber 21 is set to a specific value by removing the residual gas by evacuating the processing chamber 21 with the gas evacuation unit 23, and then the gas supply system 46 supplies CF₄, CH₃F, N₂ and O₂ gas to the processing chamber 21, under the condition of controlling a flow rate ratio CH₃F/CF₄ (a ratio of a flow rate of CH₃F gas to a flow rate of CF₄ gas) to be in the range of 0.2˜2, for example. Subsequently, an electric power of, e.g., 60 MHz, 1500 W or thereabove serving as the first high frequency wave is applied to the upper electrode 4, and an electric power of, e.g., 13.56 MHz, 600 W or thereabove serving as the second high frequency wave is applied to the lower electrode 31, thereby converting the processing gas, which is a gas mixture containing the aforementioned gases, into a plasma.

Since the plasma contains an active species of a compound of carbon and fluorine CF_{Z1}; an active species of a compound of carbon, hydrogen, and fluorine CH_{Z2}F_{Z3}; an active species of N₂; and an active species of O₂, if the SiOC film 54 is exposed to these active species atmospheres, SiF_{Z4}, CO, CH_{Z5} and CH_{Z6} will be generated, and the SiOC film 54 will start to be removed thereby. Herein, Z₁ to Z₆ are natural numbers. At this time, though O₂ gas highly improves the etching rate while the diameter of the hole 55 slightly increases, the etching (main etching) on the SiOC film 54 can still proceed without O₂ gas.

The SiOC film 54 is etched as shown in FIG. 2C in the aforementioned manner, and on the other hand, the deposits are deposited on the wall surface of the recessed portion of the SiOC film 54 due to the active species of CH_{Z2}F_{Z3}. Therefore, the etching can proceed while the widening of the recessed portion is suppressed by properly balancing the etching and the deposition. Such effect, which suppresses the widening of the recessed portion, is substantial when the electric power supplied to the upper electrode 4 is over 1500 W, as clearly shown in the embodiment to be described later. The reason can be conjectured that, the widening of the recessed portion cannot be suppressed without setting the electric power of the first high frequency wave to be high because the activation level of CH₃F gas is closely related with the deposition.

The sequence of the main etching in the etching of the SiOC film 54 is preset to stop the main etching, for example, just before the SiC film 53 serving as an etching stopper for the layer therebelow is about to be slightly exposed in a part of the wafer W or the etching is about to reach the SiC film 53. Further, CH₃F gas is used as the gas for generating the deposits, but without being restricted thereto, CH₂F₂ or CHF₃ gas can be also used.

(Step 3: Overetching)

After completing the main etching, the generation of a plasma in the processing chamber 21 is stopped by stopping the powers supplied from the high frequency power supplies 4a and 31a, and then the gas supply from the gas supply system 46 is stopped. Thereafter, the vacuum level of the processing chamber 21 is set to a specific value by removing the residual gas by evacuating the processing chamber 21 by using the gas evacuation unit 23, and then an etching referred to as an overetching is performed.

The overetching is a process provided in order to perform the etching to reach an identical depth in both central and peripheral portion of the wafer W. To be specific, the main etching is stopped at the moment when just a little amount of the SiOC film 54 (e.g., 5 nm) is left at the lower side, and then the overetching is performed with a gas having a selectivity between the SiOC film 54 and the SiC film 53 therebelow higher than the selectivity of the gas used in the main etching. Therefore, the etching can uniformly reach the top surface of the SiC film 53 in all patterns, as shown in FIG. 2D.

Thereafter, processes such as an ashing of the resist mask 51, a cleaning, a visual inspection are performed in conventional manner.

In the above-described embodiment, the pre-processing for decreasing the opening size of the resist mask 51, as shown in FIG. 2B, is performed. At this time, since the deposits generated at the sidewall of the hole 55, which is the opening portion of the resist mask 51, have etching resistance, they are not etched in the etching. Therefore, a pattern having a size smaller than the pattern provided at the resist mask 51 can be formed on the SiOC film 54.

Subsequently, the SiOC film 54 is etched by supplying the first high frequency wave, which is for converting the gas mixture containing CF₄, CHF₃, N₂, and O₂ gas into a plasma, to the processing gas atmosphere, wherein an electric power supplied to the upper electrode 4 or the lower electrode 31 by the first high frequency wave divided by a surface area of the substrate is equal to or greater than 1500 W/70685.8 mm². From this, the diameter of the hole or the width of the groove, each for burying wirings, can be suppressed to be small with a good etching profile of the hole 55 (the contact hole or the via hole) ensured, and also, the recessed portion having the size (the diameter of the hole or the width of the groove) smaller than the opening size of the opening portion of the resist mask 51 can be formed.

Accordingly, designed or nearly designed device characteristics can be obtained even in a regime where the target size of the recessed portion is so minute that it is difficult to achieve such size in the opening portion of the mask pattern by the resist mask forming technique. Further, since it is possible to form a recessed portion having an opening size smaller than that of the resist mask 51 on a film to be etched, the electrodes buried in the holes 55 will not be short-circuited even if a distance between the holes 55 (e.g., via holes and/or contact holes) adjacent to each other is reduced.

In accordance with the present invention, by performing the etching of the wafer W after being subjected to the aforementioned pre-processing, a small-sized pattern can be formed on the wafer in comparison with a case of performing the etching without the pre-processing, so that a conventional process may be used as an etching process of the SiOC film 54. In this etching, a gas mixture containing C₄F₈, CO and N₂ gas, for example, can be used.

Further, in case of the aforementioned etching, which uses a gas mixture containing CF₄, CHF₃, N₂ and O₂ gas, the pre-processing in accordance with the present invention need not be performed on the resist mask 51.

As for the wafer W on which the plasma processing is performed in accordance with the present invention, the resist mask 51 can be formed not only directly on the insulating film such as the SiOC film 54, but also on an antireflection film for preventing reflection during an exposure disposed between the SiOC film 54 and the resist mask 51. Further, an oxide film, such as an SiO₂ film, can be disposed between the insulating film and the antireflection film. The insulating film is not restricted to the SiOC film 54, but any film capable of being etched with the plasma processing method in accordance with the present invention, e.g., an oxide film, such as an SiOCH film or an SiO₂ film, or an nitride film, such as an SiON film, can be used.

As the plasma processing apparatus 2 used in accordance with the present invention, the first high frequency wave for converting the processing gas into plasma can be supplied to the lower electrode 31, instead of the upper electrode 4 (the so-called “lower electrode/dual frequency configuration”).

(Experiments)

Hereinafter, experiments performed in order to verify the effects of the present invention will be described.

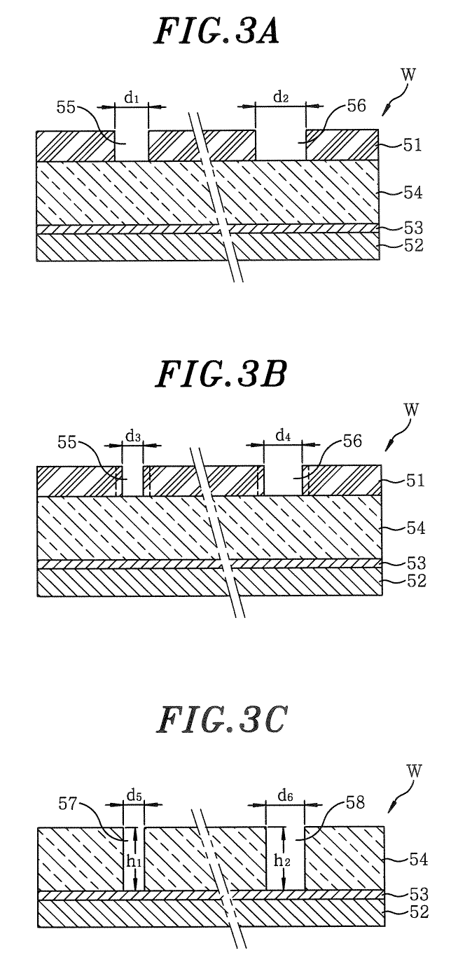

The wafer W used in the following experiments included an SiC film 53 with a film thickness of 50 nm, which was laminated on a Cu wiring 52 formed on a bare silicon wafer with a diameter of 300 mm and served as an etching stopper; an SiOC film 54 with a film thickness of 250 nm laminated on the SiC film 53; and a resist mask 51 formed with a resist film with a film thickness of 200 nm laminated on the SiOC film 54. As shown in FIG. 3A, at the resist mask 51, a pattern for forming the hole 55, which was for burying a connection electrode for connecting the wirings of each insulating film; and a pattern corresponding to the groove 56, which was referred to as a guard ring and enclosed each chip device's area, were formed. Hereinafter, for convenience of an explanation, the patterns of the resist mask 51 will be referred to as the holes 55 and the grooves 56.

Before the experiments, a cross section of the wafer W used in the experiments was observed with an SEM (Scanning Electron Microscope), and the observation result showed that, the diameter d₁ of the bottom portion of the hole 55 of the resist mask 51 (i.e., an interface between the resist mask 51 and the SiOC film 54) and the width d₂ of the bottom portion of the groove 56 of the resist mask 51 were 86 nm and 142 nm, respectively. In the following experimental examples, d1 and d2 were measured by the same method. Further, in each experiment, the apparatus shown in FIG. 1 was used as an apparatus for performing the plasma processing on the wafer W.

### EXPERIMENTAL EXAMPLE 1

### Evaluation Test of the Pre-Processing

A pre-processing on the wafer W was performed under the following process condition.

frequency of the upper electrode 4 60 MHz

electric power of the upper electrode 4: described separately

frequency of the lower electrode 31: 13.56 MHz

electric power of the lower electrode 31: 300 W

processing pressure: 6.7 Pa (50 mTorr)

processing gas CF₄/CH₃F=200/10 sccm

processing time: 15 sec

The electric power of the upper electrode 4 was set differently in each of the following examples.

### TEST EXAMPLE 1-1

In the above-described process condition, the electric power of the upper electrode 4 was set to 1000 W.

### TEST EXAMPLE 1-2

In the above-described process condition, the electric power of the upper electrode 4 was set to 1500 W.

### TEST EXAMPLE 1-3

In the above-described process condition, the electric power of the upper electrode 4 was set to 2000 W.

### TEST EXAMPLE 1-4

In the above-described process condition, the electric power of the upper electrode 4 was set to 2500 W.

### TEST EXAMPLE 1-5

In the above-described process condition, the electric power of the upper electrode 4 was set to 3000 W.

### COMPARATIVE EXAMPLE 1

In the above-described process condition, the electric power of the upper electrode 4 was set to 500 W.

(Experimental Data)

After performing the pre-processing on the wafer W, the diameter d₃ of the bottom portion of the hole 55 of the resist mask 51 and the width d₄ of the bottom portion of the groove 56 of the resist mask 51 were measured (see FIG. 3B).

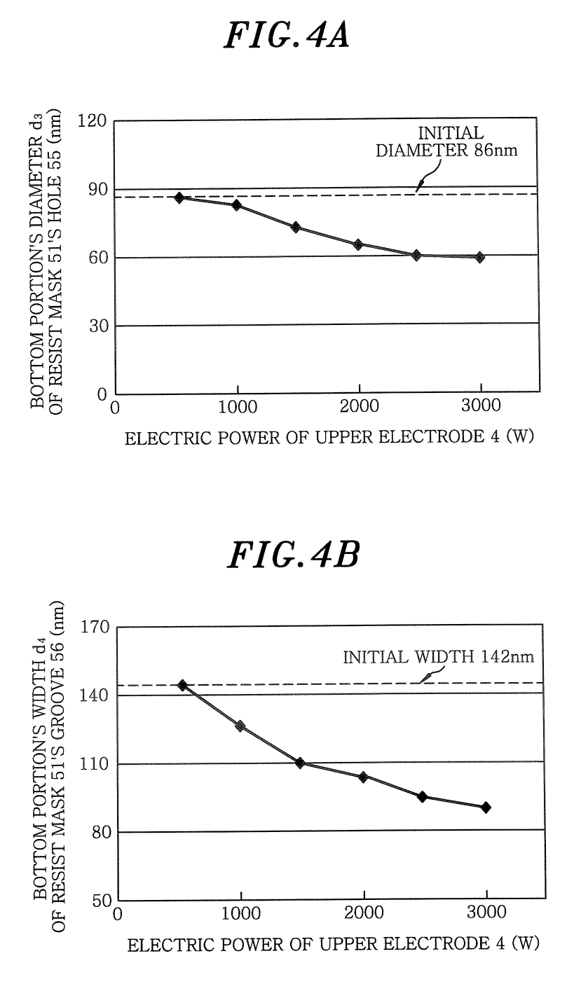

The result is shown in FIGS. 4A and 4B. In all test examples of the experimental example 1, it was confirmed that the SiOC film 54 was not etched while the deposits were formed at the sidewall of the hole 55 and the groove 56, thereby verifying the effect that the diameter d₁ of the bottom portion of the hole 55 and the width d₂ of the bottom portion of the groove 56 were decreased. When the electric power of the upper electrode 4 was 1000 W, though the diameter d₃ of the bottom portion of the hole 55 was hardly changed, the width d₄ of the bottom portion of the groove 56 was decreased from 142 nm (before the pre-processing) to 127 nm, and thus, it can be said that there is a noticeably evident effect when the electric power of the upper electrode 4 is over 1000 W.

Further, though the wafer W in the SEM picture before performing the pre-processing is different from the wafer W in the SEM picture after performing the pre-processing, that does not hinder the evaluation because the uniformity of the patterns of the resist mask 51 in a wafer W as well as in wafers W different from each other is very high. It is conjectured that, the deposits formed at the sidewall of the hole 55 and the groove 56 had been generated also at the bottom of the hole 55 and the groove 56, but the deposits generated at the bottom of the hole 55 and the groove 56 were removed because the etching rate and the generating rate of the deposits were appropriately balanced at the bottom of the hole 55 and the groove 56.

Since the pre-processing was performed while the electric power of the lower electrode 31 was set to a low electric power such that the etching of the SiOC film 54 did not proceed, and since 02 gas or the like having a large etching effect was not used, it is considered that the SiOC film 54 was not etched. The diameter d₃ of the bottom portion of the hole 55 and the width d₄ of the bottom portion of the groove 56 were decreased as the electric power of the upper electrode 4 was increased, and such effect became noticeably evident when the electric power of the upper electrode 4 was over 1000 W. Further, in this experiment, on the sidewalls of the hole 55 and the groove 56 provided at the resist mask 51, the deposits were generated uniformly between the top surface of the resist mask 51 and the SiOC film 54, and thus, the hole 55 and the groove 56 after performing the pre-processing had the same shapes as those before performing the pre-processing. That is, the hole 55 and the groove 56 after pre-processing had sidewalls formed in a vertical direction with respect to the wafer W.

### EXPERIMENTAL EXAMPLE 2

### Evaluation Test of the Pre-Processing

Next, the pre-processing of the wafer W was performed under the same condition as that of the experimental example 1, except that the electric power of the upper electrode 4 was set to 2000 W; and that the flow rate of CH₃F gas was changed in order to make the flow rate ratio CH₃F/CF₄ (the ratio of the flow rate of CH₃F gas to the flow rate of CF₄ gas) 0˜0.2. The reason for using the flow rate ratio CH₃F/CF₄, i.e., the ratio of the flow rate of CH₃F gas to the flow rate of CF₄ gas, as a parameter is as follows. As described above, CF₄ gas mainly serves as an etchant for etching the deposits generated at the sidewall of the hole 55 and the groove 56 provided at the resist mask 51, and CH₃F gas mainly serves as a gas for generating deposits for protecting the sidewall thereof from being etched by CF₄ gas Therefore, the flow rate ratio of such gases is considered to have an effect on the generation of the deposits.

### TEST EXAMPLE 2-1

The flow rate of CH₃F gas was set to 10 sccm in order to make the flow rate ratio CH₃F/CF₄ 0.05.

### TEST EXAMPLE 2-2

The flow rate of CH₃F gas was set to 20 sccm in order to make the flow rate ratio CH₃F/CF₄ 0.1.

### TEST EXAMPLE 2-3

The flow rate of CH₃F gas was set to 30 sccm in order to make the flow rate ratio CH₃F/CF₄ 0.15.

### TEST EXAMPLE 2-4

The flow rate of CH₃F gas was set to 40 sccm in order to make the flow rate ratio CH₃F/CF₄ 0.2.

### COMPARATIVE EXAMPLE 2

The flow rate of CH₃F gas was set to 0 sccm in order to make the flow rate ratio CH₃F/CF₄ O.

(Experimental Data)

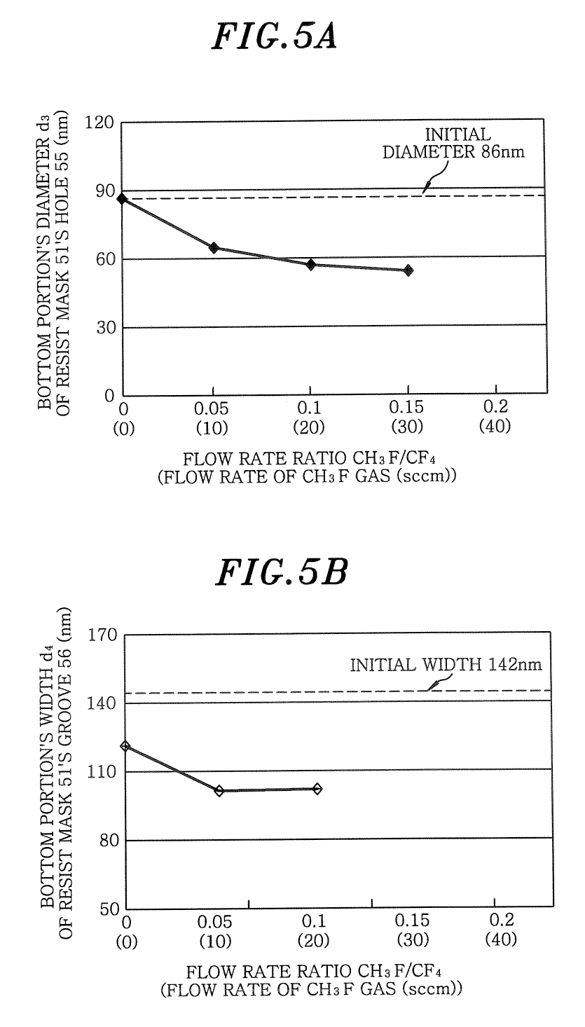

The diameter d₃ of the bottom portion of the hole 55 of the resist mask 51 and the width d₄ of the groove 56 of the resist mask 51 were measured under each process condition. The result is shown in FIGS. 5A and 5B. Both the diameter d₃ of the bottom portion of the hole 55 and the width d₄ of the groove 56 were decreased when the flow rate of CH₃F gas was increased in order to make the flow rate ratio CH₃F/CF₄ (the ratio of the flow rate of CH₃F gas to the flow rate of CF₄ gas) over 0.05 (the flow rate of CH₃F gas is over 10 sccm).

However, in cases where the flow rate ratio CH₃F/CF₄ was increased to 0.2 (the flow rate of CH₃F gas is 40 sccm) for processing the hole 55 and to 0.15 (the flow rate of CH₃F gas is 30 sccm) for processing the groove 56, the deposits were generated not only at the sidewall of the hole 55 and the groove 56 but also at the bottom thereof. The reason is conjectured that, the generating rate of the deposits was higher than the etching rate thereof, at the bottom of the hole 55 and the groove 56. From this, CF₄ gas is found to mainly serve as the etchant to perform the etching of the deposits and CH₃F gas mainly is found to serve as a gas for generating the deposits.

In performing the etching of the SiOC film 54 after the deposits are generated at the bottom of the hole 55 and the groove 56, it can be conjectured that the pattern becomes of poor shape due to the stop of the etching of the SiOC film 54 or the inhibition of the proceeding thereof by the deposits. From this experimental data, it can be said that, an available range of the flow rate ratio CH₃F/CF₄ is below 0.15 (the flow rate of CH₃F gas is 30 sccm) for the hole 55 and below 0.1 (the flow rate of CH₃F gas is 20 sccm) for the groove 56, respectively.

### EXPERIMENTAL EXAMPLE 3

### Evaluation Test of the Pre-Processing

An experiment for testing how the state of the etching was changed by changing the processing gas used in the pre-processing and performing the etching of the SiOC film 54 after the pre-processing was performed. The process condition is as follows.

(Pre-Processing)

frequency of the upper electrode 4: 60 MHz

electric power of the upper electrode 4: 2000 W

frequency of the lower electrode 31: 13.56 MHz

electric power of the lower electrode 31: 300 W

processing pressure: 6.7 Pa (50 mTorr)

processing gas: described separately

(Main Etching)

frequency of the upper electrode 4: 60 MHz

electric power of the upper electrode 4: 2000 W

frequency of the lower electrode 31: 13.56 MHz

electric power of the lower electrode 31: 600 W

processing pressure: 4.0 Pa (30 mTorr)

processing gas: CF₄/CH₃F/N₂/O₂=50/40/330/10 sccm

(Overetching)

frequency of the upper electrode 4 and the lower electrode 31: same as those in the main etching

electric power of the upper electrode 4: 400 W

electric power of the lower electrode 31: 1700 W

processing pressure: 6.7 Pa (50 mTorr)

processing gas: C₄F₈/Ar/N₂=10/1000/120 sccm

### TEST EXAMPLE 3

processing gas in the pre-processing: CF₄/CH₃F 200/10 scam

### COMPARATIVE EXAMPLE 3

processing gas in the pre-processing: C₄F₈/N₂=10/300 scam

(Experimental Data)

Cross sectional shapes of the hole 55 and the groove 56 formed on the SiOC film 54 after the etching were observed by using the SEM.

According to the observation result, the cross sections of the hole and the groove of the SiOC film 54, which had been etched after being subjected to the pre-processing under the process condition of the test example 3, were of good shape, but at the cross sections of the hole and the groove of the SiOC film 54, which had been etched after being subjected to the pre-processing under the process condition of the comparative example 3, stepped portions were generated. To be specific, the hole (or the groove) had a wide upper portion, a stepped portion formed on the way to the lower portion, and narrow lower portion Since the deposits had not been generated at the sidewall of the hole 55 and the groove 56 of the resist mask 51 under the process condition of the comparative example 3, the resist mask 51 was etched during the etching of the SiOC film 54, thereby damaging the etching profile of the SiOC film 54.

### EXPERIMENTAL EXAMPLE 4

### Evaluation Test of the Etching

By using the wafer W before being subjected to the pre-processing, the SiOC film 54 was etched under the process condition as follows.

processing gas in the main etching: described separately

other conditions: same as those in the experimental example 3

(Overetching)

each condition: same as that in the experimental example 3

TEST EXAMPLE 4-1

processing gas in the main etching CF₄/CH₂F₂/N₂/O₂=50/40/330/10 sccm

### TEST EXAMPLE 4-2

processing gas in the main etching CF₄/CH₃F/N₂/O₂=50/40/330/10 sccm

### COMPARATIVE EXAMPLE 4

processing gas in the main etching: C₄F₈/CO/N₂=10/90/330 sccm

(Experimental Data)

After etching the wafer W, the resist mask 51 was removed by the ashing process, and then the cross sectional shapes of the hole and the groove formed at the SiOC film 54 were observed with the SEM to measure the diameter d₅ of the top portion of the hole 57 of the SiOC film 54 and the width d₆ of the top portion of the groove 58 of the SiOC film 54, as shown in FIG. 3C. Since there were found no differences both between the depths of the holes 57 from the top surface of the SiOC film 54 and between the depths of the grooves 58 from the top surface of the SiOC film 54 under the different process conditions, the diameter of the hole 57 and the width of the groove 58 were evaluated without normalization, as follows.

In case the wafer W was etched under the process condition of the comparative example 4, the diameter d5 of the top portion of the hole 57 of the SiOC film 54 was 143 nm and the width d6 of the top portion of the groove 58 of the SiOC film 54 was 207 nm. On the other hand, in case the SiOC film 54 was etched under the process condition of the test example 4-1, the diameter d5 of the top portion of the hole 57 of the SiOC film 54 was 123 nm and the width d6 of the top portion of the groove 58 of the SiOC film 54 was 188 nm, thereby verifying the reduction in the hole 57 and the groove 58. Also, in case of the etching under the process condition of the test example 4-2, the diameter d5 of the top portion of the hole 57 of the SiOC film 54 was 114 nm and the width d6 of the top portion of the groove 58 of the SiOC film 54 was 188 nm, thereby verifying the reduction in the hole 57 and the groove 58.

Though the processing gas used under the process condition of the test examples 4-1 and 4-2 contains oxygen gas which causes an erosion of the resist mask 51, the reduction in the hole 57 and the groove 58 was verified in these test examples. Accordingly, it can be conjectured that, the gases contained in the processing gas were converted into a plasma during the main etching, and formed the deposits, which protected the top surface of the resist mask 51 and the sidewall of the hole 55 and the groove 56 of the resist mask 51.

### EXPERIMENTAL EXAMPLE 5

### Evaluation Test of Pre-Processing+Etching

In the test example 4-2 of the experimental example 4, before etching the SiOC film 54, the pre-processing was performed on the resist mask 51 under the condition of the test example 1-3 of the experimental example 1. As a result of the synergy of the pre-processing and the etching, the diameter of the top portion of the hole 57 of the SiOC film 54 was measured to be 91 nm and the width of the top portion of the groove 58 of the SiOC film 54 was measured to be 165 nm, after the etching. From this, it is found that the pre-processing and the etching, as consecutive processes, can be performed on the wafer W, without inhibiting the effect of each other.

### EXPERIMENTAL EXAMPLE 6

### Evaluation Test of the Etching

By using the wafer W before being subjected to the pre-processing, the main etching was performed on the SiOC film 54 under the same condition as that of the test example 4-2 of the experimental example 4. During the main etching, the electric power of the upper electrode 4 was varied as follows, thereby investigating the effect of the electric power of the upper electrode 4 on the suppression of the recessed portion of the SiOC film 54.

### TEST EXAMPLE 6-1

The electric power of the upper electrode 4 was set to 1000 W.

### TEST EXAMPLE 6-2

The electric power of the upper electrode 4 was set to 1500 W.

### TEST EXAMPLE 6-3

The electric power of the upper electrode 4 was set to 2000 W.

### TEST EXAMPLE 6-4

The electric power of the upper electrode 4 was set to 2500 W.

### TEST EXAMPLE 6-5

The electric power of the upper electrode 4 was set to 3000 W.

### COMPARATIVE EXAMPLE 6-1

The electric power of the upper electrode 4 was set to 0 W. In general, plasma is not generated at 0 W. However, since the electric power of 600 W was applied to the lower electrode 31 in this example, plasma was generated and the SiOC film 54 was etched under such condition.

### COMPARATIVE EXAMPLE 6-2

The electric power of the upper electrode 4 was set to 500 W.

(Experimental Data)

After etching the SiOC film 54, the cross sectional shapes of the hole 57 and the groove 58 of the SiOC film 54 were observed with SEM, to measure the diameter d₅ of the top end of the hole 57; the width d₆ of the top end of the groove 58; the depth h₁ of the hole 57 from the top surface of the SiOC film 54; and the depth h₂ of the groove 58 from the top surface of the SiOC film 54, as shown in FIG. 3C.

In the experimental example 6, since the SiOC film 54 was etched more deeply as the electric power of the upper electrode 4 was increased, it was doubtful whether or not to directly compare the diameters d₅ of the top portion of the hole 57 of the SiOC film 54 and the widths d₆ of the top portion of the groove 58 of the SiOC film 54 under each process condition was an appropriate evaluation. Thus, in order to relatively compare the etching results from each process condition, each of the increment of the diameter of the hole 57 by the etching and the increment of the width of the groove 58 by the etching was divided by the depth thereof after the etching, i.e., the increment of the diameter of the hole 57 per a unit depth was normalized to r₁ (r₁=(d₅−d₁)/h₁) and the increment of the width of the groove 58 per a unit depth was normalized to r₂ (r₁=(d₆−d₂)/h₂) for the evaluation. Accordingly, these values indicate the taper level of the hole 57 or the groove 58 formed at the SiOC film 54, and the smaller values indicate the larger suppressing effect on the widening.

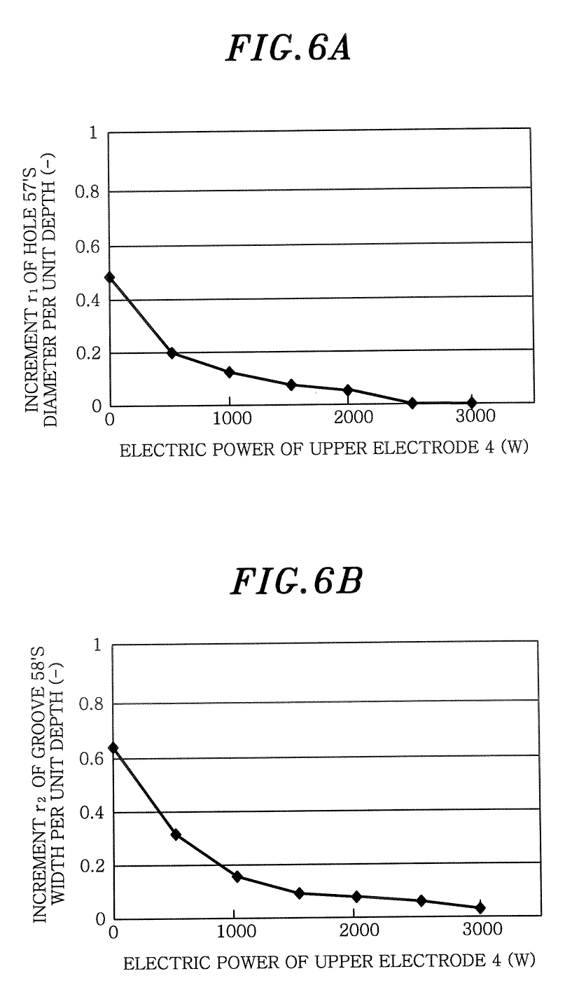

The result is shown in FIGS. 6A and 6B. Both the increment of the diameter of the hole 57 per a unit depth r₁ and the increment of the width of the groove 58 per a unit depth r₂ were decreased as the electric power of the upper electrode 4 was increased, and the decrement was remarkably evident when the electric power of the upper electrode 4 was increased to be over 1500 W. Further, at 3000 W, both the increment of the diameter of the hole 57 per a unit depth r₁ and the increment of the width of the groove 58 per a unit depth r₂ approached nearly zero, which indicates that the diameter of the hole 57 and the width of the groove 58 were not increased after the etching. Because the diameter of the wafer W is 300 mm, it can be said that, if the electric power per a unit area of the wafer W, which is supplied from the upper electrode 4, is over 0.021 W/mm² (1500 W/70685.8 mm²), the suppressing effect on the widening of the recessed portion (the hole 57 or the groove 58) will be large in etching the SiOC film 54.

### EXPERIMENTAL EXAMPLE 7

### Evaluation Test of the Etching

By using the wafer W before being subjected to the pre-processing, as was same in the experimental example 6, the main etching was performed on the SiOC film 54 under the same condition as that of the test example 6-3 of the experimental example 6. During the main etching, the flow rate of CH₃F gas was varied to make the flow rate ratio CH₃F/CF₄ (the ratio of the flow rate of CH₃F gas to the flow rate of CF₄ gas) 0˜1.2, thereby investigating the effect of the flow rate ratio CH₃F/CF₄ on the reduction of the recessed portion of the SiOC film 54.

### TEST EXAMPLE 7-1

The flow rate CH₃F was set to 10 sccm in order to make the flow rate ratio CH₃F/CF₄ 0.2.

### TEST EXAMPLE 7-2

The flow rate CH₃F was set to 20 sccm in order to make the flow rate ratio CH₃F/CF₄ 0.4.

### TEST EXAMPLE 7-3

The flow rate CH₃F was set to 30 sccm in order to make the flow rate ratio CH₃F/CF₄ 0.6.

### TEST EXAMPLE 7-4

The flow rate CH₃F was set to 40 sccm in order to make the flow rate ratio CH₃F/CF₄ 0.8.

### TEST EXAMPLE 7-5

The flow rate CH₃F was set to 50 sccm in order to make the flow rate ratio CH₃F/CF₄ 1.

### TEST EXAMPLE 7-6

The flow rate CH₃F was set to 60 sccm in order to make the flow rate ratio CH₃F/CF₄ 1.2.

### COMPARATIVE EXAMPLE 7

The flow rate CH₃F was set to 0 sccm in order to make the flow rate ratio CH₃F/CF₄ 0.

(Experimental Data)

After performing the etching of the SiOC film 54, as was the same in the experimental example 6, the increment of the diameter of the hole 57 per a unit depth r₁ and the increment of the width of the groove 58 per a unit depth r₂ were measured.

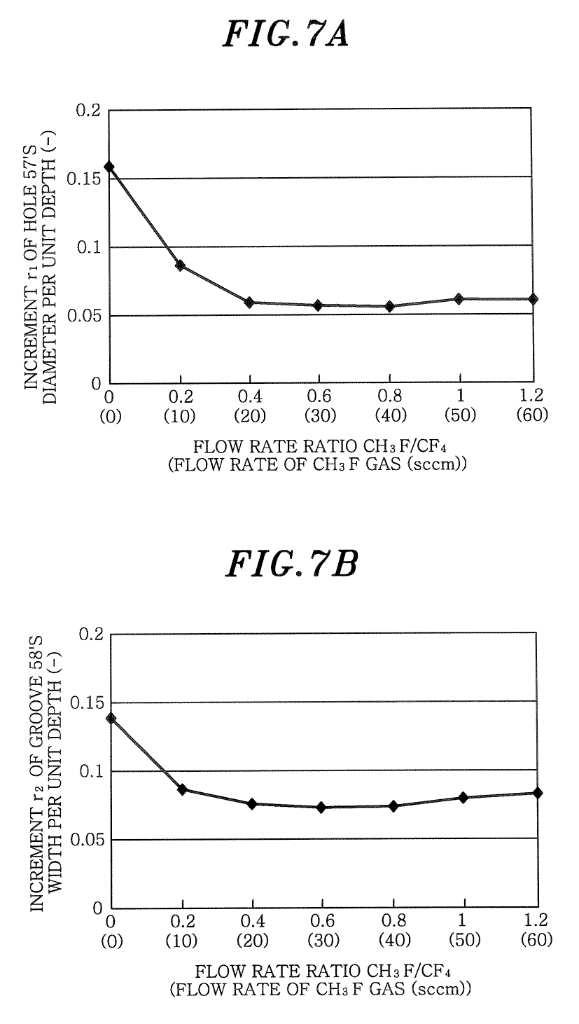

The result is shown in FIGS. 7A and 7B. Both the increment of the diameter of the hole 57 per a unit depth r₁ and the increment of the width of the groove 58 per a unit depth r₂ were decreased when the flow rate of CH₃F gas was increased in order to make the flow rate ratio CH₃F/CF₄, (the ratio of the flow rate of CH₃F gas to the flow rate of CF₄ gas) over 0.2 (the flow rate of CH₃F gas was over 10 sccm). However, the decrease stopped when the flow rate ratio CH₃F/CF₄ was about 0.4 (the flow rate of CH₃F gas was 20 sccm), and both r₁ and r₂ tended to increase slightly when the flow rate ratio CH₃F/CF₄ was over 1 (the flow rate of CH₃F gas was 50 sccm).

From this, in this etching, though the exact reason is not found because the reaction mechanism is complex due to the simultaneous progress of the generation of the etching-resistant deposits at the sidewall of the hole 55 and the groove 56 of the resist mask 51; and the etching of the SiOC film 54, it can be conjectured that, when the flow rate of CH₃F gas was increased, deposits having a low adhesive strength and a low etching resistance were formed at the upper portion of the hole 57 and the groove 58 of the SiOC film 54. However, the amount of the deposits generated is extremely small, and thus, it can be confirmed that there is a suppressing effect on the widening of the hole 57 and the groove 58 of the SiOC film 54 in comparison with the comparative example 7 in which CH₃F gas was not used. Though not shown in FIGS. 7A and 7B, it was found that the suppressing effect continues until the flow rate ratio CH₃F/CF₄ became 2 (the flow rate of CH₃F gas was 100 sccm) in both the hole 57 and the groove 58, so that the upper limit of the available range of the flow rate ratio CH₃F/CF₄ can be determined as 2.

### EXPERIMENTAL EXAMPLE 8

### Evaluation Test of the Pre-Processing+the Etching

On each wafer W after being subjected to the pre-processing under the process conditions of the test examples 1-1, 1-3 and 1-5 in the experimental example 1, the etching was performed under the process conditions of the test examples 6-1, 6-3 and 6-5 in the experimental example 6. To be specific, in the pre-processing and the etching, the experiment was performed while the electric power of the upper electrode 4 was varied, respectively. The combination of the process conditions of the pre-processing and the etching is as follows.

### TEST EXAMPLE 8-1

After performing the pre-processing under the process condition of the test example 1-1 (the electric power of the upper electrode 4 was set to 1000 W), the etching was performed under the process condition of the test example 6-1 (the electric power of the upper electrode 4 was set to 1000 W).

### TEST EXAMPLE 8-2

After performing the pre-processing under the process condition of the test example 1-1 (the electric power of the upper electrode 4 was set to 1000 W), the etching was performed under the process condition of the test example 6-3 (the electric power of the upper electrode 4 was set to 2000 W).

### TEST EXAMPLE 8-3

After performing the pre-processing under the process condition of the test example 1-1 (the electric power of the upper electrode 4 was set to 1000 W), the etching was performed under the process condition of the test example 6-5 (the electric power of the upper electrode 4 was set to 3000 W).

### TEST EXAMPLE 8-4

After performing the pre-processing under the process condition of the test example 1-3 (the electric power of the upper electrode 4 was set to 2000 W) the etching was performed under the process condition of the test example 6-1 (the electric power of the upper electrode 4 was set to 1000 W).

### TEST EXAMPLE 8-5

After performing the pre-processing under the process condition of the test example 1-3 (the electric power of the upper electrode 4 was set to 2000 W), the etching was performed under the process condition of the test example 6-3 (the electric power of the upper electrode 4 was set to 2000 W).

### TEST EXAMPLE 8-6

After performing the pre-processing under the process condition of the test example 1-3 (the electric power of the upper electrode 4 was set to 2000 W), the etching was performed under the process condition of the test example 6-5 (the electric power of the upper electrode 4 was set to 3000 W).

### TEST EXAMPLE 8-7

After performing the pre-processing under the process condition of the test example 1-5 (the electric power of the upper electrode 4 was set to 3000 W), the etching was performed under the process condition of the test example 6-1 (the electric power of the upper electrode 4 was set to 1000 W).

### TEST EXAMPLE 8-8

After performing the pre-processing under the process condition of the test example 1-5 (the electric power of the upper electrode 4 was set to 3000 W), the etching was performed under the process condition of the test example 6-3 (the electric power of the upper electrode 4 was set to 2000 W).

### TEST EXAMPLE 8-9

After performing the pre-processing under the process condition of the test example 1-5 (the electric power of the upper electrode 4 was set to 3000 W), the etching was performed under the process condition of the test example 6-5 (the electric power of the upper electrode 4 was set to 3000 W).

(Experimental Data)

After performing the pre-processing and the etching of the SiOC film 54 in each example, the increment of the diameter of the hole 57 per a unit depth r₁ and the increment of the width of the groove 58 per a unit depth r₂ were measured.

The result is shown in Table 1. In the experimental example 8, the effect verified in the experimental example 1 (in case the electric power of the upper electrode 4 was increased in the pre-processing, the diameter d₁ of the bottom portion of the hole 55 of the resist mask 51 and the width d₂ of the bottom portion of the groove 56 of the resist mask 51 were decreased) and the effect verified in the experimental example 6 (in case the electric power of the upper electrode 4 was increased in the etching, the increment of the diameter of the hole 57 per a unit depth r₁ and the increment of the width of the groove 58 per a unit depth r₂ were decreased) worked together without inhibiting the effect of each other, thereby decreasing the diameter d₅ of the hole 57 and the width d₆ of the groove 58 of the SiOC film 54. From this, it can be conjectured that, the diameter d₃ of the hole 55 and the width d₄ of the groove 56, which are decreased by the pre-processing, are maintained until the SiOC film 54 is subjected to the etching. Further, the data in Table 1 have minus values, which indicates that, in comparison with the size (d₁ or d₂) of the bottom portion of the pattern (the hole 55 or the groove 56) of the resist mask 51 before performing the pre-processing, the size (d₅ or d₆) of the pattern (the hole 57 or the groove 58) of the SiOC film 54 after performing the etching is decreased.

TABLE 1

| Electric power of | | |
|---|---|---|
| upper electrode 4 in | | |
| pre-processing (W) | | |
| 1000 | 2000 | 3000 |

(a) increment of diameter of hole 57 per unit depth r1(−)

| | | | | |
|---|---|---|---|---|
| Electric power of | 1000 | −0.05 | −0.17 | −0.23 |
| upper electrode 4 in | 2000 | −0.05 | −0.21 | −0.26 |
| main etching (W) | 3000 | −0.14 | −0.23 | −0.29 |

(b) increment of width of groove 58 per unit depth r2(−)

| | | | | |
|---|---|---|---|---|
| Electric power of | 1000 | −0.13 | −0.44 | −0.44 |
| upper electrode 4 in | 2000 | −0.29 | −0.44 | −0.52 |
| main etching (W) | 3000 | −0.31 | −0.50 | −0.53 |

While the invention has been shown and described with respect to the preferred embodiments, it will be understood by those skilled in the art that various changes and modifications may be made without departing from the scope of the invention as defined in the following claims.

What is claimed is:

1. A plasma processing method for processing a substrate by using a plasma processing apparatus having a first high frequency power supply, wherein the first high frequency power supply is connected to one of an upper electrode and a lower electrode facing to each other and supplies a first high frequency wave to a processing gas atmosphere in order to convert a processing gas into a plasma, the method comprising the steps of:
mounting the substrate, in which a resist mask is laminated on an insulating film made of a low-k film containing silicon and oxygen, on the lower electrode;
supplying the processing gas, which contains CF-based compound made of carbon and fluorine and CHₓF_{y} (a sum of x and y equals four, each of them being a natural number), to the processing gas atmosphere;
generating plasma by converting the processing gas into a plasma by supplying the first high frequency wave to the processing gas atmosphere, and decreasing an opening size of an opening portion of the resist mask by depositing deposits at a sidewall thereof; and
etching the insulating film by using the plasma.

2. The plasma processing method of claim 1, wherein the step for decreasing the opening size is performed while a bias power is supplied to the substrate mounted on the lower electrode, by supplying a second high frequency wave, which has a frequency lower than that of the first high frequency wave, to the processing gas atmosphere by using a second high frequency power supply connected to the lower electrode.

3. The plasma processing method of claim 1, wherein an electric power of the first high frequency wave supplied to the upper electrode or the lower electrode divided by a surface area of the substrate is equal to or greater than 1000 W/70685.8 mm².

4. The plasma processing method of claim 1, wherein a flow rate ratio of the CHₓF_{y} gas to the CF-based gas is equal to or greater than 0.05.

5. The plasma processing method of claim 1, wherein the step for etching the insulating film by using the plasma includes the steps of:
supplying the processing gas, which contains CF₄, CHₓF_{y} (a sum of x and y equals four, each of them being a natural number) and N₂, to the processing gas atmosphere; and
generating the plasma by converting the processing gas into the plasma by supplying the first high frequency wave to the processing gas atmosphere, wherein the electric power supplied to the upper electrode or the lower electrode by the first high frequency wave divided by the surface area of the substrate is equal to or greater than 1500 W/70685.8 mm², and etching the insulating film by using the plasma while the bias power is supplied to the substrate mounted on the lower electrode, by supplying the second high frequency wave, which has a frequency lower than that of the first high frequency wave, to the processing gas atmosphere by using the second high frequency power supply connected to the lower electrode.

6. A plasma processing method for processing a substrate by using a plasma processing apparatus having a first high frequency power supply and a second high frequency power supply, wherein the first high frequency power supply is connected to one of an upper electrode and a lower electrode facing to each other and supplies a first high frequency wave to a processing gas atmosphere in order to convert a processing gas into a plasma; and wherein a second high frequency power supply is connected to the lower electrode and supplies a second high frequency wave, which has a frequency lower than that of the first high frequency wave, to the processing gas atmosphere in order to supply a bias power to the substrate mounted on the lower electrode, the method comprising the steps of:
mounting the substrate, in which a resist mask is laminated on an insulating film made of a low-k film containing silicon and oxygen, on the lower electrode;
supplying the processing gas, which contains CF₄, CHₓF_{y} (a sum of x and y equals four, each of them being a natural number) and N₂, to the processing gas atmosphere; and
generating the plasma by converting the processing gas into the plasma by supplying the first high frequency wave to the processing gas atmosphere, wherein the electric power supplied to the upper electrode or the lower electrode by the first high frequency wave divided by a surface area of the substrate is equal to or greater than 1500 W/70685.8 mm², and etching the insulating film by using the plasma by supplying the second high frequency wave to the processing gas atmosphere.

7. The plasma processing method of claim 5, wherein a flow rate ratio of the CF₄ gas to the CHₓF_{y} gas is equal to or greater than 0.2 and equal to or smaller than 2.

8. The plasma processing method of claim 6, wherein a flow rate ratio of the CF₄ gas to the CHₓF_{y} gas is equal to or greater than 0.2 and equal to or smaller than 2.

9. A plasma processing apparatus for etching an insulating film of a substrate in which a resist mask is laminated on the insulating film made of a low-k film containing silicon and oxygen, the apparatus comprising:
a processing chamber;
an upper electrode and a lower electrode disposed in the processing chamber to face to each other;
a first high frequency power supply, wherein the first high frequency power supply is connected to one of the upper electrode and the lower electrode and supplies a first high frequency wave to a processing gas atmosphere in order to convert a processing gas into a plasma;
a supply unit for supplying the processing gas, which contains CF-based compound made of carbon and fluorine and CHₓF_{y} (a sum of x and y equals four, each of them being a natural number), to the processing chamber; and
a control unit for performing the plasma processing method of claim 1.

10. A plasma processing apparatus for etching an insulating film of a substrate in which a resist mask is laminated on the insulating film made of a low-k film containing silicon and oxygen, the apparatus comprising:
a processing chamber;
an upper and a lower electrode disposed in the processing chamber to face to each other;
a first high frequency power supply, wherein the first high frequency power supply is connected to the upper electrode and supplies a first high frequency wave to a processing gas atmosphere in order to convert a processing gas into plasma;
a second high frequency power supply, wherein the second high frequency power supply is connected to the lower electrode and supplies a second high frequency wave, which has a frequency lower than that of the first high frequency wave, to the processing gas atmosphere in order to supply a bias power to the substrate mounted on the lower electrode;
a supply unit for supplying the processing gas, which contains CF-based compound made of carbon and fluorine and CHₓF_{y} (a sum of x and y equals four, each of them being a natural number), to the processing chamber; and
a control unit for performing the plasma processing method of claim 2.

11. A plasma processing apparatus for etching an insulating film of a substrate in which a resist mask is laminated on the insulating film made of a low-k film containing silicon and oxygen, the apparatus comprising:
a processing chamber;
an upper and a lower electrode disposed in the processing chamber to face to each other;
a first high frequency power supply, wherein the first high frequency power supply is connected to one of the upper electrode and the lower electrode and supplies a first high frequency wave to a processing gas atmosphere in order to convert a processing gas into a plasma;
a second high frequency power supply, wherein the second high frequency power supply is connected to the lower electrode and supplies a second high frequency wave, which has a frequency lower than that of the first high frequency wave, to the processing gas atmosphere in order to supply a bias power to the substrate mounted on the lower electrode;
a supply unit for supplying the processing gas containing CF₄, CHₓF_{y} (a sum of x and y equals four, each of them being a natural number) and N₂, to the processing chamber; and
a control unit for performing the plasma processing method of claim 6.

12. A storage medium for storing therein a computer program to be run on a computer, the program used in a plasma processing apparatus having a first high frequency power supply and a second high frequency power supply, wherein the first high frequency power supply is connected to one of an upper electrode and a lower electrode facing to each other and supplies a first high frequency wave to a processing gas atmosphere in order to convert a processing gas into plasma; and wherein the second high frequency power supply is connected to the lower electrode and supplies a second high frequency wave, which has a frequency lower than that of the first high frequency wave, in order to supply a bias power to the substrate mounted on the lower electrode,
wherein the computer program includes steps for performing the plasma processing method of claim 1.
